(19) United States
(12) Patent Application Publication
(10) Pub. No.: US 2023/0334192 A1
(43) Pub. Date: Oct. 19, 2023

(54) MODEL-BASED SYSTEM ENGINEERING ANALYSIS TOOL FOR DIGITAL MODELING OF SYSTEMS OF SYSTEMS

(71) Applicant: The MITRE Corporation, McLean, VA (US)

(72) Inventors: Judith S. DAHMANN, Alexandria, VA (US); Nathan NORWOOD, San Diego, CA (US); Allison KHAW, Jamaica Plain, MA (US)

(73) Assignee: The MITRE Corporation, McLean, VA (US)

(21) Appl. No.: 17/721,091

(22) Filed: Apr. 14, 2022

(51) Int. Cl. G06F 30/20

(52) U.S. Cl. CPC G06F 30/20

(57) ABSTRACT

Described herein are systems and methods for generating digital models for systems of systems. In one or more examples, an end to end (E2E) model of the system of systems can be generated based on information regarding mission metrics and mission threads of the systems within the system of systems, as well as systems and connectivity information. In one or more examples, a user input is received indicating the analysis that is desired to be performed on the system of systems. Based on the received user inputs, in one or more examples, a portion of the E2E system of systems model is selected and copied to form a separate digital model that represents the portion of the system of systems implicated by the user inputs. In one or more examples, the systems and methods add additional information and metrics to the digital model of the portion of the system of systems.

### STATEMENT REGARDING FEDERALLY SPONSORED RESEARCH OR DEVELOPMENT

This invention was made with Government support under U.S. Government Contract No. W56KGU-18-D-0004 awarded by the Department of Defense. The Government has certain rights in this invention.

### FIELD OF THE DISCLOSURE

This disclosure relates to performing Model-Based System Engineering (MBSE) analysis on complex Systems of Systems (SoS), and more specifically to a modeling and analysis technique that can reduce the time and computational resources needed to apply digital engineering to large scale enterprises.

### BACKGROUND OF THE DISCLOSURE

Model-based system engineering, a technique in which systems are represented using models that can be analyzed to support requirements development, design, verification, and validation of systems, has been successfully employed in multiple contexts including in the design of computing, cyber-physical, and other enterprise systems. In contrast to document-based systems engineering techniques in which systems are represented using specifications and requirements databases, model-based approaches to system engineering can allow for more intuitive and meaningful analysis of a system, and thus ultimately can better support the design, development, and verification of systems.

However, as capabilities develop, separate systems can be integrated with one another to form a system of systems. While the individual systems may have developed models available to perform analysis on the individual systems themselves, applying model-based system engineering to complex systems of systems can be challenging. Each individual digital model of a system can be complex on its own. When multiple systems are integrated with one another, it can be challenging to integrate the models representing each system. Furthermore, since the models representing the system are complex, a system of systems model can be orders of magnitude more complex than any individual system model, thus making performing any meaningful analysis on them infeasible because of the amount of computing resources and/or time needed to perform an analysis on such a complex model.

Using models of individual systems to generate an overall model of a system of systems may be both time and resource prohibitive and thus may not be a good approach to applying model-based system engineering techniques to complex systems of systems. However, the ability to use model-based system engineering analysis on complex systems of systems is still desirable given the breadth and efficiency of the analysis that is enabled by such analysis.

### SUMMARY OF THE DISCLOSURE

Described herein are systems and methods for generating digital models for systems of systems. In one or more examples, a simplified end to end (E2E) model of the system of systems can be generated based on information regarding mission metrics and mission threads of the systems within the system of systems, as well as systems and connectivity information regarding the entire systems of systems. Once the E2E model has been created, in one or more examples, a user input is received indicating the analysis that is desired to be performed on the system of systems. Based on the received user inputs, in one or more examples, a portion of the E2E system of systems model is selected and copied to form a separate digital model that represents the portion of the system of systems implicated by the user inputs. In one or more examples, the systems and methods add additional information and metrics to the digital model of the portion of the system of systems. This enables the generation of a complete digital model that can accurately perform the analysis indicated by the user's inputs.

In one or more examples, a method for generating an enhanced digital model for of a system of systems comprises: generating an end-to-end model of the system of systems, wherein the end-to-end model of the system of systems comprises a plurality of constituent systems of the systems of systems (SoS), and one or more connections between the plurality of constituent systems, identifying one or more constituent systems of the SoS required to perform an analysis of the SoS, generating a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS, and associating data to the one or more constituent systems of the digital model, and generating an enhanced analysis model based on the generated digital model and the data associated to the one or more constituent systems of the digital model.

Optionally, generating the end-to-end model comprises: identifying the plurality constituent systems belonging to the SoS, and identifying the one or more connections between the plurality of constituent systems;

Optionally, generating the end-to-end model comprises: identifying one or more mission threads associated with the SoS, and associating the one or more mission threads with plurality of constituent systems or the one or more connections between the plurality of constituent systems.

Optionally, generating the end-to-end model comprises: identifying one or more mission metrics associated with the SoS, and associating the one or more mission metrics with plurality of constituent systems or the one or more connections between the plurality of constituent systems.

Optionally, wherein identifying one or more constituent systems of the SoS required to perform the analysis of the SoS comprises: labelling each constituent system of the plurality of constituent systems with one or more stereotypes, selecting a stereotype of the one or more stereotypes, and identifying the one or more constituent systems of the SoS required to perform the analysis of the SoS based on the selected one or more stereotypes.

Optionally, identifying the one or more constituent systems of the SoS required to perform the analysis of the SoS comprises: labelling one or more mission threads associated with the plurality of constituent systems with one or more stereotypes, selecting a stereotype of the one or more stereotypes, and identifying the one or more constituent systems of the SoS required to perform the analysis of the SoS based on the mission threads associated with the selected one or more stereotypes.

Optionally, generating the digital model comprises: specifying one or more criteria associated with the digital model; and selecting one or more constituent systems from the end-to-end model based on the identified one or more constituent systems of the SoS and the one or more criteria associated with the digital model.

Optionally, the one or more criteria associated with the digital model comprises a degree of connectivity between the identified constituent systems, and other constituent systems of the plurality of constituent systems of the end-to-end model.

Optionally, the data associated to the one or more constituent systems of the digital model includes information pertaining to the operation of the one or more constituent systems associated with the data.

Optionally, the end-to-end model, the digital model, and the enhanced analysis model are generated using SysML.

In one or more examples, a system for generating an enhanced digital model for of a system of systems comprises: a memory, one or more processors, wherein the memory stores one or more programs that when executed by the one or more processors, cause the one or more processors to: generate an end-to-end model of the system of systems, wherein the end-to-end model of the system of systems comprises a plurality of constituent systems of the systems of systems (SoS), and one or more connections between the plurality of constituent systems, identify one or more constituent systems of the SoS required to perform an analysis of the SoS, generate a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS; and associate data to the one or more constituent systems of the digital model, and generate an enhanced analysis model based on the generated digital model and the data associated to the one or more constituent systems of the digital model.

Optionally, generating the end-to-end model comprises: identifying the plurality constituent systems belonging to the SoS, and identifying the one or more connections between the plurality of constituent systems;

Optionally, generating the end-to-end model comprises: identifying one or more mission threads associated with the SoS, and associating the one or more mission threads with plurality of constituent systems or the one or more connections between the plurality of constituent systems.

Optionally, generating the end-to-end model comprises: identifying one or more mission metrics associated with the SoS, and associating the one or more mission metrics with plurality of constituent systems or the one or more connections between the plurality of constituent systems.

Optionally, identifying one or more constituent systems of the SoS required to perform the analysis of the SoS comprises: labelling each constituent system of the plurality of constituent systems with one or more stereotypes, selecting a stereotype of the one or more stereotypes, and identifying the one or more constituent systems of the SoS required to perform the analysis of the SoS based on the selected one or more stereotypes.

Optionally, identifying the one or more constituent systems of the SoS required to perform the analysis of the SoS comprises: labelling one or more mission threads associated with the plurality of constituent systems with one or more stereotypes, selecting a stereotype of the one or more stereotypes, and identifying the one or more constituent systems of the SoS required to perform the analysis of the SoS based on the mission threads associated with the selected one or more stereotypes.

Optionally, generating the digital model comprises: specifying one or more criteria associated with the digital model; and selecting one or more constituent systems from the end-to-end model based on the identified one or more constituent systems of the SoS and the one or more criteria associated with the digital model.

Optionally, the one or more criteria associated with the digital model comprises a degree of connectivity between the identified constituent systems, and other constituent systems of the plurality of constituent systems of the end-to-end model.

Optionally, the data associated to the one or more constituent systems of the digital model includes information pertaining to the operation of the one or more constituent systems associated with the data.

Optionally, the end-to-end model, the digital model, and the enhanced analysis model are generated using SysML.

In one or more examples, a non-transitory computer readable storage medium storing one or more programs for generating an enhanced digital model for of a system of systems, the programs for execution by one or more processors of an electronic device that when executed by the device, cause the device to: generate an end-to-end model of the system of systems, wherein the end-to-end model of the system of systems comprises a plurality of constituent systems of the systems of systems (SoS), and one or more connections between the plurality of constituent systems; identify one or more constituent systems of the SoS required to perform an analysis of the SoS, generate a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS, and associate data to the one or more constituent systems of the digital model; and generate an enhanced analysis model based on the generated digital model and the data associated to the one or more constituent systems of the digital model.

Optionally, generating the end-to-end model comprises: identifying the plurality constituent systems belonging to the SoS, and identifying the one or more connections between the plurality of constituent systems;

Optionally, generating the end-to-end model comprises: identifying one or more mission threads associated with the SoS, and associating the one or more mission threads with plurality of constituent systems or the one or more connections between the plurality of constituent systems.

Optionally, generating the end-to-end model comprises: identifying one or more mission metrics associated with the SoS, and associating the one or more mission metrics with plurality of constituent systems or the one or more connections between the plurality of constituent systems.

Optionally, identifying one or more constituent systems of the SoS required to perform the analysis of the SoS comprises: labelling each constituent system of the plurality of constituent systems with one or more stereotypes, selecting a stereotype of the one or more stereotypes, and identifying the one or more constituent systems of the SoS required to perform the analysis of the SoS based on the selected one or more stereotypes.

Optionally, identifying the one or more constituent systems of the SoS required to perform the analysis of the SoS comprises: labelling one or more mission threads associated with the plurality of constituent systems with one or more stereotypes, selecting a stereotype of the one or more stereotypes, and identifying the one or more constituent systems of the SoS required to perform the analysis of the SoS based on the mission threads associated with the selected one or more stereotypes.

Optionally, generating the digital model comprises: specifying one or more criteria associated with the digital model; and selecting one or more constituent systems from the end-to-end model based on the identified one or more constituent systems of the SoS and the one or more criteria associated with the digital model.

Optionally, the one or more criteria associated with the digital model comprises a degree of connectivity between the identified constituent systems, and other constituent systems of the plurality of constituent systems of the end-to-end model.

Optionally, the data associated to the one or more constituent systems of the digital model includes information pertaining to the operation of the one or more constituent systems associated with the data.

Optionally, the end-to-end model, the digital model, and the enhanced analysis model are generated using SysML.

### BRIEF DESCRIPTION OF THE FIGURES

The invention will now be described, by way of example only, with reference to the accompanying drawings, in which:

FIGS. 1A-1B illustrate an exemplary aircraft system of systems according to examples of the disclosure.

FIG. 2 illustrates an exemplary method for generating a digital model of a system of systems according to examples of the disclosure.

FIG. 3 illustrates an exemplary end to end top level model of a system of systems according to examples of the disclosure.

FIG. 4 illustrates an exemplary process for generating an end to end top level model of a system of systems according to examples of the disclosure.

FIG. 5 illustrates an exemplary snippet of the end-to-end top level model of a system of systems according to examples of the disclosure.

FIG. 6 illustrates an exemplary process for generating a snippet of the end-to-end top level model of a system of systems according to examples of the disclosure.

FIGS. 7A-7B illustrate an exemplary E2E model with applied stereotypes and an exemplary snippet according to examples of the disclosure

FIG. 8 illustrates an exemplary process for generating an enhanced analysis model based on a generated snippet according to examples of the disclosure.

FIG. 9 illustrates an exemplary computing system, according to examples of the disclosure.

### DETAILED DESCRIPTION OF THE DISCLOSURE

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Described herein are systems and methods for generating digital engineering environments to address mission level system of systems requirements, analysis, engineering and portfolio management. In one or more examples, the systems and methods described herein can be used to perform digital engineering on SoS architectures. In one or more examples, a user can generate a top-level end-to-end (E2E) model of the SoS. In one or more examples, the SoS can include information about the components of the system and their connectivity. In one or more examples, the E2E model can also include information regarding mission level metrics and mission threads (i.e., tasks to be performed as part of the operation of the SoS). In one or more examples, the E2E model can be created by a user using a general-purpose architecture modeling language such as Systems Modeling Language (SysML). In one or more examples, a user, can specify the information needed to create the E2E model. Additionally or alternatively, the information required to create the E2E model can be obtained from other digital models of the individual components of the SoS and design documents associated with the SoS.

In one or more examples, the systems and methods can include providing a graphical user interface to a user, which allows the user to select the portion of the E2E model they would like to use to generate an enhanced model to be used for a particular analysis. In one or more examples, the user can select one or more components, mission threads, and/or mission metrics to be included in a particular analysis, and based on the user selection, the systems and methods described herein can generate an enhanced model (i.e., a “snippet”) using the E2E model. In one or more examples, the snippet can represent a portion or sub-set of the components and connection associated with the E2E model of the SoS. In one or more examples, the user can apply one or more stereotypes to the components and sub-components of the E2E model. Applying stereotypes is a modeling technique to include additional metrics and metadata associated with a particular type of system or component. In one or more examples, the user can generate enhanced models based on the stereotypes applied to the components and sub-components captured in an E2E model.

In one or more examples, once the snippet has been created, the user can then be directed to upload or provide additional information and data about the components in the enhanced model so as to form a detailed digital engineering model of the snippet which can be used to performing an analysis by one or more simulations or other analytical tools. In this way, rather than attempting to create a detail enhanced model of a large and complex SoS which can drain computational resources and be difficult to maintain, the user can create customizable snippets of the SoS which only include the components that are germane to the type of analysis the user wishes to perform, thus improving digital engineering processes and system engineering processes for complex SoS.

In the following description of the various embodiments, it is to be understood that the singular forms “a,” “an,” and “the” used in the following description are intended to include the plural forms as well, unless the context clearly indicates otherwise. It is also to be understood that the term “and/or” as used herein refers to and encompasses any and all possible combinations of one or more of the associated listed items. It is further to be understood that the terms “includes, “including,” “comprises,” and/or “comprising,” when used herein, specify the presence of stated features, integers, steps, operations, elements, components, and/or units but do not preclude the presence or addition of one or more other features, integers, steps, operations, elements, components, units, and/or groups thereof.

Certain aspects of the present disclosure include process steps and instructions described herein in the form of an algorithm. It should be noted that the process steps and instructions of the present disclosure could be embodied in software, firmware, or hardware and, when embodied in software, could be downloaded to reside on and be operated from different platforms used by a variety of operating systems. Unless specifically stated otherwise as apparent from the following discussion, it is appreciated that, throughout the description, discussions utilizing terms such as “processing,” “computing,” “calculating,” “determining,” “displaying,” “generating” or the like, refer to the action and processes of a computer system, or similar electronic computing device, that manipulates and transforms data represented as physical (electronic) quantities within the computer system memories or registers or other such information storage, transmission, or display devices.

The present disclosure in some embodiments also relates to a device for performing the operations herein. This device may be specially constructed for the required purposes, or it may comprise a general purpose computer selectively activated or reconfigured by a computer program stored in the computer. Such a computer program may be stored in a non-transitory, computer readable storage medium, such as, but not limited to, any type of disk, including floppy disks, USB flash drives, external hard drives, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each connected to a computer system bus. Furthermore, the computing systems referred to in the specification may include a single processor or may be architectures employing multiple processor designs, such as for performing different functions or for increased computing capability. Suitable processors include central processing units (CPUs), graphical processing units (GPUs), field programmable gate arrays (FPGAs), and ASICs.

The methods, devices, and systems described herein are not inherently related to any particular computer or other apparatus. Various general-purpose systems may also be used with programs in accordance with the teachings herein, or it may prove convenient to construct a more specialized apparatus to perform the required method steps. The required structure for a variety of these systems will appear from the description below. In addition, the present invention is not described with reference to any particular programming language. It will be appreciated that a variety of programming languages may be used to implement the teachings of the present disclosure as described herein.

A “system of systems” can refer to a plurality of systems that are interconnected with one another to form a new and more complex system than the individual systems that make up the components of the SoS. In one or more examples, a system of systems can represent a collection systems, each capable of independent operation, that interoperate together to achieve additional desired capabilities. In today's networked world, very few systems, if any, stand alone. As an example, information technology (IT) systems and applications, as it is with most military, air traffic control, and other cyber-physical systems are made up of multiple complex systems that are independently operated, but work together to execute a common mission.

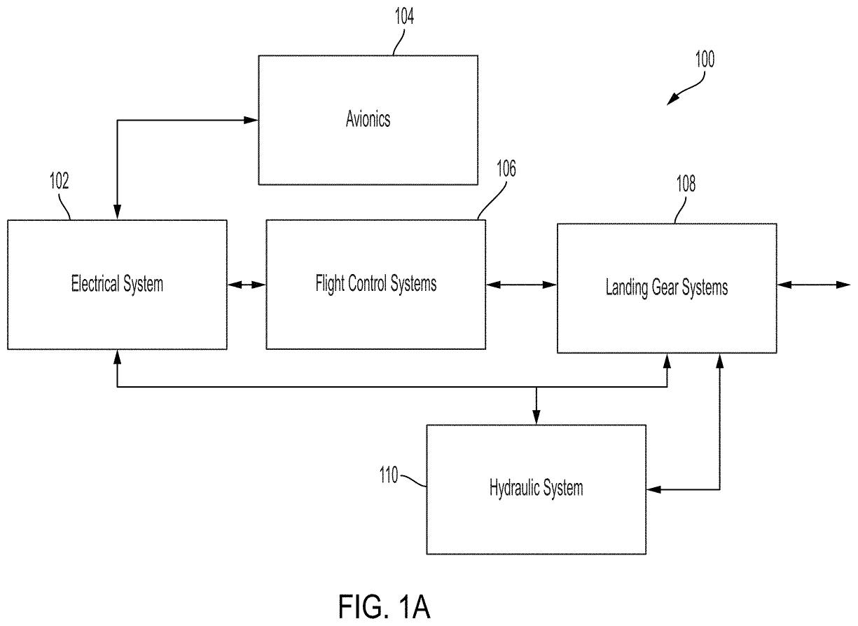

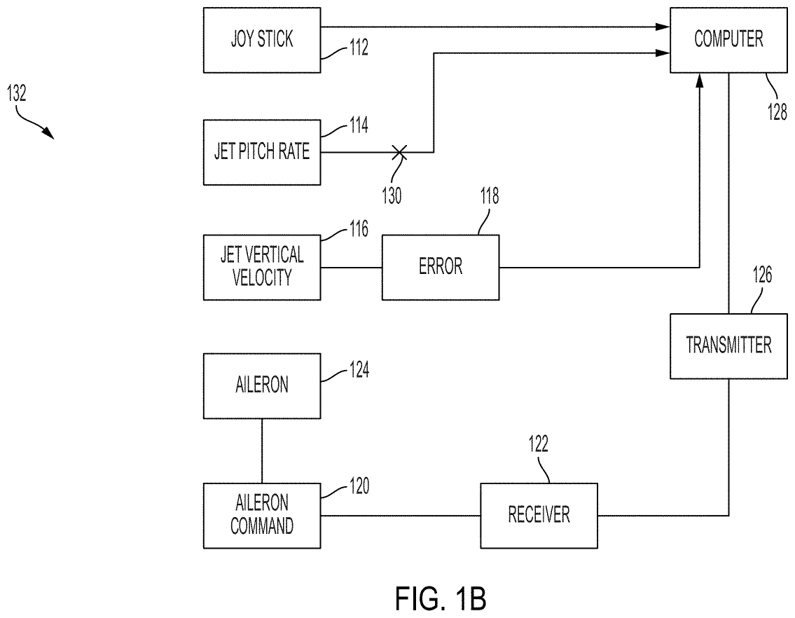

As an example of an SoS, FIGS. 1A-1B illustrate an exemplary aircraft system of systems according to examples of the disclosure. In one or more examples the system 100 of FIG. 1A can represent a system diagram of an aircraft including the systems that work together to allow the aircraft to fulfill its mission of flying from a point of origin to a particular destination. In one or more the aircraft system of systems 100 can include an electrical system 102 that can include a battery, generator, and/or alternator as well as an electrical bus that is configured to provide and distribute electrical power to each of the other systems that make up the aircraft. In one or more examples, the system 100, can include an avionics system 104 that include the electronics associated with navigation, monitoring, and the autopilot features of the aircraft. In one or more examples, the system 100 can include a flight control system 106 that is configured to control the pitch, yaw, and roll of the aircraft so as to control the direction and altitude of the aircraft. In one or more examples, the aircraft SoS 100 includes a landing gear system 108 that is configured to deploy and retract the landing of the gear of the aircraft. In one or more examples, the aircraft SoS can also include a hydraulic system 110 that can operate the hydraulics that can be used to control various systems of the aircraft. The example systems shown in FIG. 1A are just meant as examples and are not meant to be a comprehensive system diagram of an aircraft. In one or more examples, and aircraft will include far more systems that are not depicted in FIG. 1A.

In one or more examples, each of the constituent systems 102, 104, 106, 108, and 110 of SoS 100 can perform operations that are independent from one another as well as perform operations that work in conjunction with one another. For instance, in one or more examples, the electrical system 102 can work to provide power to the other systems so that they can each in turn perform their particular tasks. In one or more examples, a portion of the systems 102, 104, 106, 108, and 110 can work with one another to perform certain mission threads associated with the operation of the aircraft. For instance, in one or more examples, the hydraulic system 110 can operate the components of the landing gear system 108, to perform a missing thread of deploying the landing gear, while the electrical system 102 can power various sensors in the landing gear system 108 to determine whether the landing gear has successfully deployed. Thus, the systems 102, 108, and 110 can work with one another to deploy the landing gear.

In one or more examples, each of the constituent systems 102, 104, 106, 108, and 110 of SoS 100 can also be systems in their own right, meaning each of the systems can include components that work in conjunction with one another to perform tasks associated with the mission of the system to which they belong. For instance, FIG. 1B illustrates an exemplary flight control system 132, which can correspond to the components that make up the flight control system 106 of FIG. 1A. The system 132 can include a joystick 112 that can represent the controls a pilot would use engage to control the aircraft and, specifically, the controls of the aileron. The output of the joystick 1′2 can be transmitted to a flight computer model 128. Computer 128 can take in multiple inputs in addition to the input from the joystick 112 as specified above. As illustrated in FIG. 1, the computer 128 can also receive signals from jet pitch rate sensor model 114, as well as jet vertical velocity sensor model 116, via error correction module 118. Jet pitch rate sensor 1 114 can be configured to read the pitch rate of the aircraft and then generate signals that are transmitted to the computer 128. The jet vertical velocity sensor 116 can be configured to determine the vertical velocity (i.e., rate of ascent and decent) of the aircraft and then generate signals that are then transmitted to the computer 128.

Computer 128 can input the signals described above and then generate signals to maneuver the ailerons of the aircraft in a specific way based on the pilot's controls and the pitch rate and vertical velocity of the aircraft. In order to effectuate movement of the aileron, computer 128 can issue a command sent to the aileron at its output. The command can be received by a transmitter 126 which in turn can modulate the received signal and transmit it to a receiver 122. The receiver 122 can then transmit the signal to an aileron command module 120, which, upon deciphering the received command, can issue a signal to aileron 124 to move according to the commands generated by computer model 128.

As described above, in the same manner as the constituent systems of aircraft SoS 100 of FIG. 1A can work in conjunction with one another to perform various mission threads associated with operation of the aircraft, each of the constituent systems can themselves be systems made up of numerous components that operate in conjunction with one another to perform the mission threads associated with the constituent system. As demonstrated above, an SoS can include numerous components with each component representing a system in its own right. As discussed in further detail below, the complex architecture of SoS can make applying digital engineering and systems engineering analysis of SoS complex and resource intensive.

In one or more examples, the constituent systems can be created independently from one another and be in operation before the system of systems is created. Thus, when a constituent system is created, it may undergo a rigorous systems engineering analysis in its own right before being deployed in a systems of systems. This analysis can include for example, modeling, requirements analysis, and simulation analysis. For instance, in one or more examples, a detailed digital model of each constituent system can be created and then used to perform simulation and analysis to determine the performance capabilities of the constituent system.

When each of the constituent system are deployed into an SoS, the SoS itself may need have the same types of analyses performed as was performed on each of the constituent systems. However, trying to create a digital model of the SoS may present a challenge due to the complexity of the SoS. Since an SoS contains multiple constituent systems, generating a digital model of the SoS that is capable of being simulated an analyzed, may be infeasible since the SoS model would need to have detailed models of each of the constituent systems and thus will be much more complex than the models of the constituent systems. In one or more examples, in order to generate a full digital model of an SoS, the models of the constituent systems (which may be complex in their own right) may need to be integrated with one another to form the model of the SoS. Performing an analysis on such a complex mode, may exhaust or severely burden computational resources used to perform an analysis, and take a great deal of time to execute, thus making such a model infeasible.

However, often a system engineering analysis of a SoS does not always require the full digital model of the SoS. For instance, a particular analysis may only implicate a subset of the constituent systems of the SoS. Thus, in order perform a particular analysis on a SoS only a portion of the SoS may need to be analyzed. Thus, often times, using a complete digital model of an SoS is wasteful. Conventionally, a user could start with a complete digital model of a SoS and manually delete the constituent systems and connection that they didn't need for their analysis to create digital model tailored to the analysis that was desired. However, such a process could be burdensome in itself, requiring the user to sift through a complex SoS model to only include the systems or components germane to the desired analysis. Such a process, in which a user creates multiple digital models out of a complex SoS model can lead to inefficiencies. For instance, in one or more examples, if different stakeholders retain disparate models of portions of an SoS, the data collected may not be coherent, consistent, or reusable, and efforts to provide mission-level effects will necessarily be fragmented and will subject the SoS to technical and operation risk. While individual analysis could be done without this type of SoS level model context, the risk is that different analyses make different, possibly unstated, assumptions about the context which may or may not align with reality. Thus, using a common SoS model to generate “enhanced models” of different portions of the SoS for purposes of analysis can be beneficial since there are possible efficiencies and a shared, explainable context for assessment of the analysis results in terms of SoS considerations. The issue to be addressed, particularly with a large complex SoS, is how to create this context in a way that it provides this coherence yet enables different stakeholders to address issues from their perspectives in the larger SoS and mission context.

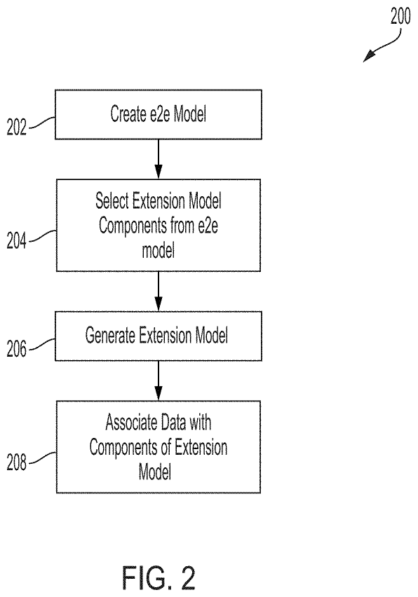

In one or more examples, in order to retain an overview of the SoS in a top-level environment, while at the same time providing enough detail to perform any detailed analysis on the SoS, in one or more examples, a top-level E2E model of an SoS is provided and can be used to create individual “snippets” that are then detailed according to the needs of a particular analysis. In this way a “digital model” of the SoS can be generated that is only as detailed as is required by a particular analysis. FIG. 2 illustrates an exemplary method for generating a digital model of a system of systems according to examples of the disclosure. In one or more examples, the process 200 of FIG. 1 can begin at step 202 with the creation of an end-to-end model of the entire SoS. In one or more examples, and as described in further detail below, the E2E model created at step 202 can represent a top-level digital representation of the entire SoS wherein the representation is limited to basic data and does not contain more detailed information about each of the constituent systems that may have been included in a digital engineering model of each of the constituent systems. As described in further detail below, the E2E model of the entire SoS can include information about the architecture of the SoS and its connectivity, the mission metrics of the SoS, as well as mission threads relating to the SoS. In one or more examples, mission metrics can include mission level performance requirements such as timing and latency requirements. In one or more examples, mission threads can refer to activities and processes performed by the one or more constituent systems in order to support the overall mission of the SoS. In or more examples, the architecture and connectivity information can refer to information pertaining to the way in which constituent systems and sub-systems of an SoS are laid out and connected to one another.

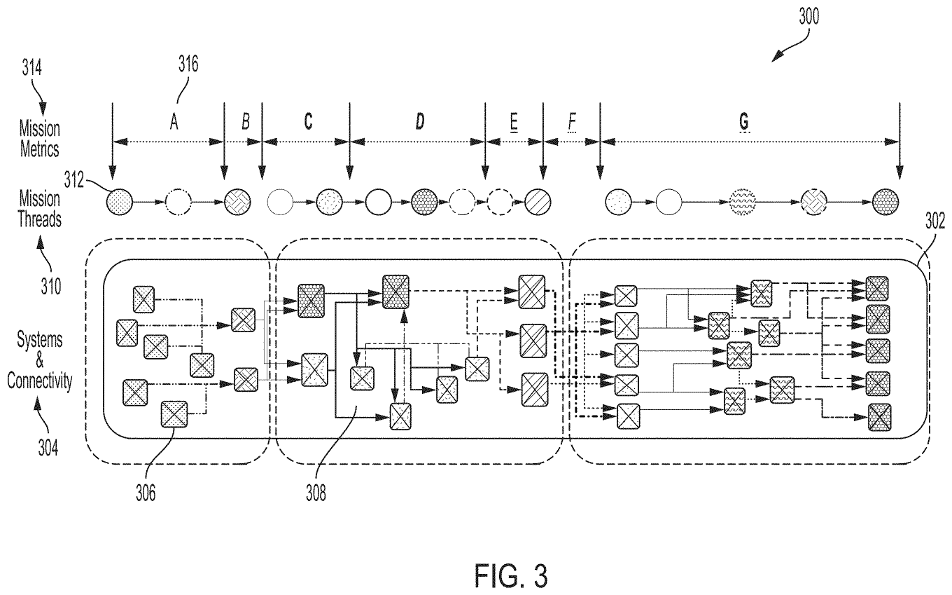

In one or more examples, the E2E model generated at step 202 can be created using a general-purpose architecture modeling language for systems engineering applications such as SysML. FIG. 3 illustrates an exemplary end to end top level model of a system of systems according to examples of the disclosure. In one or more examples, the E2E model 300 of FIG. 3 can represent a top-level diagram of an SoS with a limited set of data associated with the model, so as to reduce the complexity of the top-level diagram. In one or more examples, the E2E model 300 of FIG. 3, can include a system block diagram 302 that can represent the systems and connectivity information 304 associated with the E2E model 300. In one or more examples, the system and connectivity information 304 can include information about the constituent system/components 306 the systems of systems. This in one or more examples, each block 306 in the block diagram 302 can represent information about a particular constituent system of the systems. In one or more examples, each constituent system 306 can include information about the system or system that underlie the constituent system. In other words, in one more examples, each constituent system can include its own set of sub-systems (not pictured).

In one or more examples, the block diagram 302 as part of the systems and connectivity information 304 can include connectivity information 308 which can be represented in the diagram 302 as connection between the various constituent systems 306 of the SoS. In one or more examples, the connectivity information 308 can not only show communications links between constituent systems 306, but can also indicate the directionality of the communications link (i.e., either as bidirectional or going from one block to the other). The connectivity information 308 can work in conjunction with the constituent systems information 306 to provide the E2E model with the overall architecture of the SoS.

In one or more examples, the E2E model 300 can also include mission thread information 310. As discussed above, mission threads can refer to mission tasks that are used to support the overall mission purpose. Thus, in one or more examples, a particular mission can be composed of multiple threads 312 as show in the example E2E model 300 of FIG. 3. In one or more examples, each of the mission threads 312 can be associated with one or more constituent systems 306 and/or connections 308. Thus, in one or more examples, using a language such as SysML, a user can specify a mission thread, and then associate the mission thread 312 with one or more of the constituent components 306 and/or connections 308 that are used to carry out the specified mission thread.

In one or more examples, the E2E model 300 can include one or more mission metrics information 314. As described above, mission metrics information 314 can refer to information how performance requirements for the one or more mission threads associated with an SoS. In one or more examples, and as illustrated in FIG. 3 the E2E model 314 can include one or more metrics 316. In one or more examples, each mission metric 316 can be associated with one or more mission threads 312 by the user. Thus, in one or more examples, using a language such as SysML, a user can specify a mission metrics 316, and then associate the mission metric 316 with one or more mission threads 312 (with each of the mission threads having already been associated with one or more of the constituent components 306 and/or connections 308 that are used to carry out the specified mission thread, as described above). In one or more examples, and as described in further detail below, the mission metrics 316 can be linked to the system and or systems from the E2E diagram 300 that contribute to the metrics, thus leading to greater traceability of their impact. In one or more examples, the metrics themselves can be incorporate into the system block diagram directly.

In one or more examples, and as described above, the E2E model depicted in FIG. 3 can be created using a general-purpose architecture modeling language such as SysML. In one or more examples, the user can create the E2E in a specific manner so as to provide the necessary details to the E2E model so that a snippet (described in further detail below) can be created from the E2E model and then enhanced with further information to create an enhanced analysis model that is tailored to the analysis that is required to estimate/simulated SoS performance. In one or more examples, a user can specify an E2E model in a manner that provides not only information about the system/connectivity of the system, the mission threads, and the mission metrics, but also provides information about how each of those elements are related to one another, so that when a snippet is created, the correct information/data gets carried over into the snippet as well. As described in further detail below, a snippet can serve as the model frame for development of enhanced models to address the specific issue that a user wishes to analyze.

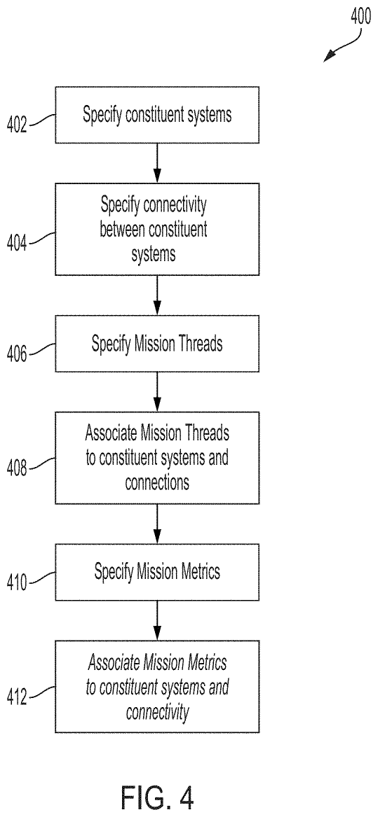

FIG. 4 illustrates an exemplary process for generating an end to end top level model of a system of systems according to examples of the disclosure. In one or more examples, the process 400 illustrated in FIG. 4 can be used to create the E2E model and include the data needed to generate a snippet as described in further detail below. In one or more examples, the process 400 can begin at step 402 wherein a user (using an architecture modeling language) specifies the constituent systems that will make up the SoS that will be represented by the E2E model. In one or more examples, the constituent systems can be specified as well as the sub-systems that make up the constituent system. Using the example of FIGS. 1A-1B as an example, at step 402, a user could specify the constituent systems 102, 104, 106, 108, and 110 of the aircraft SoS, as well as any sub-systems associated with a particular constituent system such as the sub-systems of the flight control system depicted in FIG. 1B.

In one or more examples, once the user has specified the constituent systems and sub-systems at step 402, the process can move to step 404 wherein the connectivity (i.e., the connections) between the constituent systems are specified. In one or more examples, the user can specify which systems transmit information to other systems by connecting the constituent systems thereby indicating that two constituent systems transmit data to one another. In one or more examples, two constituent systems can share information bi-directionally meaning that both constituent systems connected to one another transfer information transfer data to the other constituent system, or can also be uni-directional in which one constituent system transfers data or communicates to another constituent system. In one or more examples, at step 402, the user when specifying connectivity between two constituent systems can also specify the directionality of the communication (i.e., uni-directional or bi-directional).

In one or more examples, steps 402 and 404 can allow for the user to specify the systems and connectivity information of the E2E model described above with respect to FIG. 3 by creating the block diagram 302 which as described in further detail below can be used to generate the frame for an enhanced model (i.e., a snippet). In one or more examples, once the systems and connectivity information have been provided at steps 402 and 404, the process 400 can move to step 406 wherein mission thread information is specified by the user. In one or more examples, and at step 406, a user can specify (using SysML or another architecture modeling language), various mission threads as well as how the mission threads are related to one another. For instance, in one or more examples, various mission threads may occur in a particular sequential order, or may occur in parallel. In one or more examples, the user can specify the mission threads and the relationships between the mission threads (i.e., one mission thread flowing into another mission thread, or two mission threads occurring in parallel, etc.). In one or more examples, each mission thread specified by a user can also include one or processes that can also be specified by the user. In one or more examples, much like each constituent system can itself included underlying subsystems, each specified mission thread can include its own underlying processes that are performed in order to fulfill the machine. Thus, in one or more examples, a user when specifying a mission thread can also specify the underlying processes of the mission thread.

In one or more examples, after specifying the mission threads and the relationships between the mission threads at step 406, the process 400 can move to step 408 wherein the mission threads specified at step 406 can be associated with the constituent systems and connections between systems that are implicated by the mission threads. In one or more examples, associating the mission threads with the constituent systems and connections can include the user specifying which systems and connections specified at steps 402 and 404 are used in performing the mission thread. In this way, at step 408, the systems associated with a mission thread is identified which can ensure that any analysis involving a particular mission thread will implicate the appropriate systems and connections so that they are included in the snippet (described in further detail below).

In one or more examples, once the mission threads have been specified and associated with constituent systems and connections at steps 406 and 408, the process 400 can move to step 410 wherein one or more mission metrics can be specified by the user. In one or more examples, and as described above, the mission metrics can include published metrics that define required mission level performance. In one or more examples, metrics can represent measures of quantitative assessment that can be used for assessing, comparing, and tracking performance of various mission threads and systems associated with the SoS. In one or more example, a metric can include information about the speed at which a particular mission thread is performed, a rate of success, or any other quantitative value that can help a user to assess the performance of the one or more parts of the SoS.

In one or more examples, once the user specifies one or more metrics associated with the SoS at step 410, the process 400 can move to step 412 wherein each of the metrics specified at step 410 can be associated by the user with the constituent systems which contribute to the metric. In this way, if a user wants to perform a particular analysis involving a metric, then in one or more examples, as part of the creating a snippet based on the user's analysis, the appropriate constituent systems and connections can be pulled into the snippet to form the enhanced model needed to perform the user's desired analysis (explained in further detail below).

The process 400 of FIG. 4 can be used to create an E2E model which can include enough information about an SoS so that a snippet can be generated for a particular analysis, but which by itself doesn't include enough information to produce the detailed analysis that may be desired by the user. In this way, the SoS can be specified in a way that will not be overly complex, but will have enough information so that a detailed model of a portion of the SoS that is to be analyzed can be quickly and efficiently built using the E2E model. While individual analysis could be done without this type of SoS level model context, the risk is that different analyses make different, possibly unstated, assumptions about the context which may or may not align with reality. By offering this context (i.e., the E2E model) for use by different analyses, there are possible efficiencies and a shared, explainable context for assessment of the analysis results in terms of SoS considerations.

Using digital models of an SoS to perform various system engineering analyses, generally does not require analyzing every system and connection associated with the SoS. Instead, generally speaking, addressing a particular issue will only involve a portion of the SoS that is implicated by the issue to be analyzed. Thus, in one or more examples, the user can utilize the E2E to select the portion of the model to be used as a framework for preparing a detailed digital model by which to perform a desired analysis. The portion of the E2E model can be referred to as a snippet. In one or more examples, using the “snippet” as the base for analysis, relevant mission metrics and mission threads specified in the E2E model can also be pulled into a snippet and used in a desired analysis. In one or more examples, snippets may take different forms. For instance, in one or more examples, a snippet can include a particular network or network type in the E2E model, a platform and its connections, or a mission activities and constituent processes, all of which can contribute to a mission metric of interest.

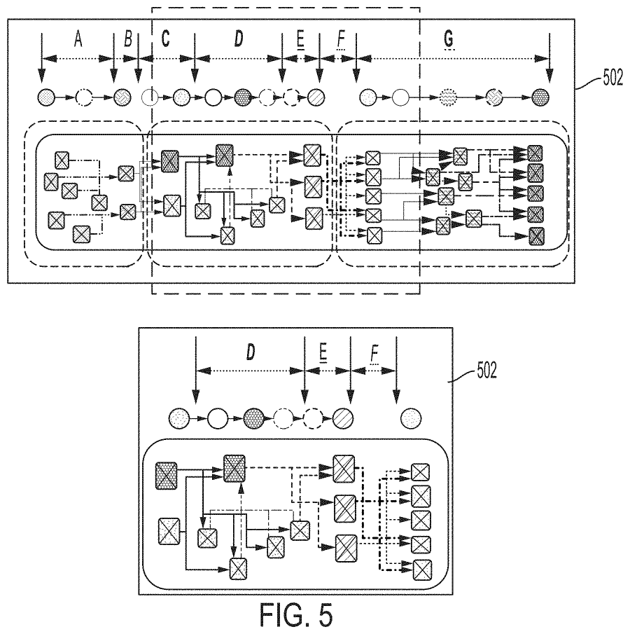

FIG. 5 illustrates an exemplary snippet of the end-to-end top level model of a system of systems according to examples of the disclosure. In one or more examples, the E2E model 502 illustrated in the example 500 can be used to generate a snippet 504. In one or more examples, and as described in further detail below, the user can specify what constituent systems, mission threads, and/or metrics to include for a snippet based on the type of analysis that they wish to conduct. In one or more examples, the snippet is then automatically generated from the E2E model based on the specifications provided by the user.

In one or more examples, a snippet 502 can include a subset of the constituent systems, a subset of the mission threads, and a subset of the mission metrics found in the E2E model. The subsets can be selected based on a user's specification (described in detail below) and based on the type of analysis the user ultimately would like to do on the SoS. In one or more examples, the generated snippets can be used to study/analyze network alternatives in the context of the SoS or analyzing mission performance.

In contrast to an example where a user could take an E2E model and remove unwanted components manually, the snippet can be generated automatically using simply a specification of the components provided by the user. Since SoS E2E diagrams can be complex and include hundreds or more constituent system, with each constituent system including in own set of components, generating a snippet manually may be just as time consuming and complex as simply running an analysis on a detailed digital model of the SoS. Thus, in one or more examples, rather than require the user to “prune” an E2E diagram, a procedure can be provided that allows the user to specify a snippet efficiently without manually having to choose the specific systems to be included in the snippet.

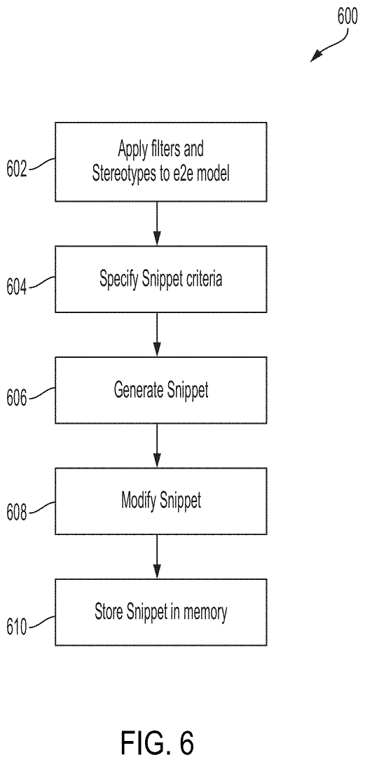

FIG. 6 illustrates an exemplary process for generating a snippet of the end-to-end top level model of a system of systems according to examples of the disclosure. In one or more examples of the disclosure, the process 600 of FIG. 6 can begin at step 602 wherein a user applies one or more filters/stereotypes to the E2E model. In one or more examples, applying a filter or stereotype can refer to a process of labelling/associating one or more constituent of systems of the E2E as belonging to a particular group. To illustrate the concept of a stereotype/filter, an example is provided

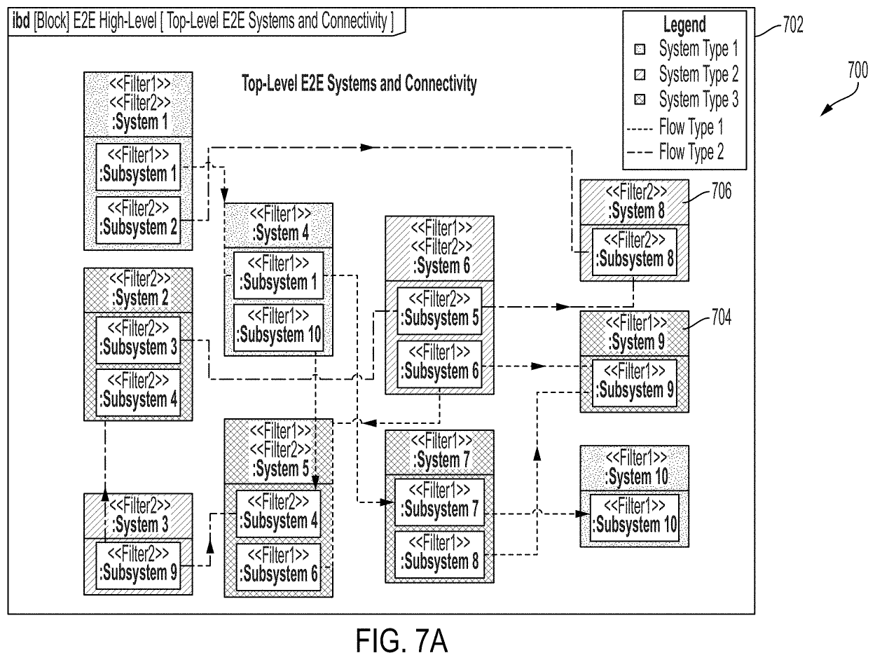

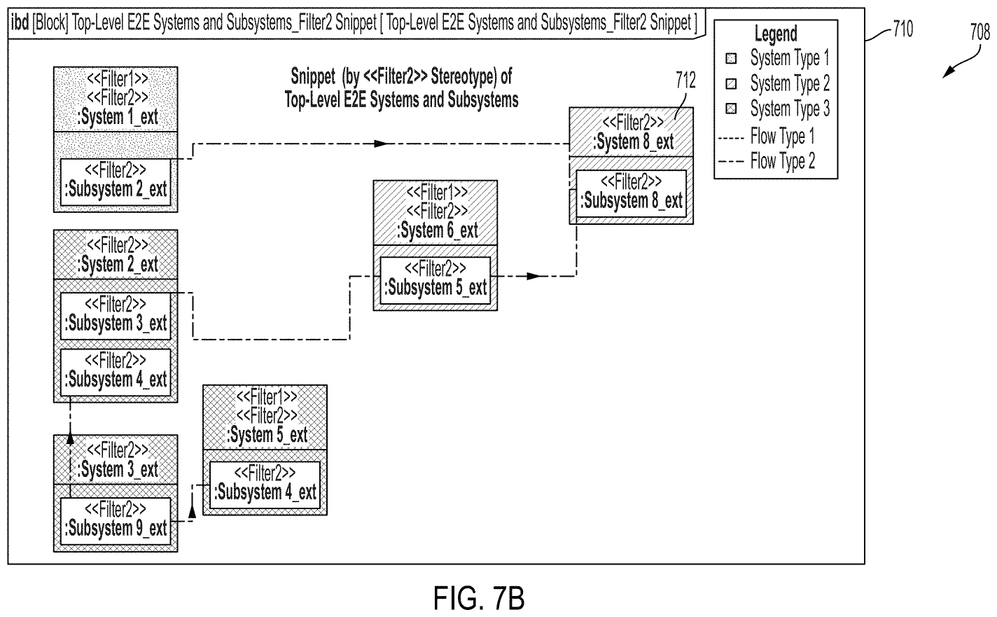

FIGS. 7A-7B illustrate an exemplary E2E model with applied stereotypes and an exemplary snippet according to examples of the disclosure. In one or more examples, the example 700 of FIG. 7A illustrates an exemplary E2E model in which each constituent system and subsystem has been labeled/stereotyped by a user. In the example 700 of FIG. 7A, each constituent system or subsystem has been labeled with either a stereotype labeled “Filter 1”, a stereotype labeled “Filter 2” or has been associated with both stereotypes. In one or more examples, the user can apply the stereotypes based on their own preferences, or can apply the stereotypes based on the blocks that are likely to be implicated in certain analyses. In one or more examples, applying stereotypes/filters at step 602 can be optional and alternative methods can be used to specify the constituent systems, mission threads, and mission metrics that should be included in a particular snippet.

Returning to the example of FIG. 6, once the stereotypes/filters have been applied at step 602, the process 600 can move to step 604 wherein the user can specify one or more criteria for a snippet. In one or more examples, and in the instance where a user has used stereotypes to classify the constituent systems and subsystems of an E2E, step 604 can include the user specifying one or more stereotypes to be included in a snippet. In one or more examples, once the user specifies the stereotypes, the process 600 can move to step 606 wherein a snippet is generated using the specified stereotype/filters.

Turning to the example of FIG. 7B, which illustrates an exemplary snippet based on a specified stereotype, the snippet 710 of example 708 can include each and every constituent system and subsystem (as well any connections between them) that have been associated with the “filter 2” stereotype such as system 712 of snippet 710. Thus, in one or more examples, the user can (for instance using a graphical user interface) specify the specific filter or filters to use in the snippet, and the snippet can be generated using the systems and connections that have been a priori associated with the filter using the process described above with respect to step 602.

In one or more examples, in addition to generating a snippet containing every system and subsystem associated with a particular stereotype/filter, any mission threads or metrics associated with the constituent systems and subsystems can also be included as part of the snippet generated at step 606. As describe above with respect the exemplary process 400 of FIG. 4, one or more mission threads and/or mission metrics can be associated with a particular constituent system and/or subsystem of the SoS. Thus, in one or more examples, if a particular system or subsystem is selected based on a user-specified stereotype, then in one or more examples, any mission threads and/or mission metrics associated with the constituent system and/or subsystem can also be included as part of the snippet.

In one or more examples, steps 604 and 606 can include specifying other criteria beyond a stereotype or filter. For instance, in one or more examples, the user could specify a particular constituent system of the E2E model, and specify a degree of connectivity such that a snippet will include the specified constituent system as well as any other constituent system that is connected to the specified constituent system within the degree of connectivity specified by the user. For instance, a connectivity of “1” can include any constituent system that is directly connected to the specified system., whereas a connectivity of “2” can include any constituent system that is either directly connected to the specified system, or is connected to a system that is then connected to the specified system.

Once the snippet has been generated at step 606, the process 600 can move to step 608 wherein the user can modify the snippet according to their desire. In one or more examples, the user may wish to remove or add systems, or may wish to add or remove mission threads and/or mission metrics. In one or more examples, once the user has completed modifying the snippet (which is optional) at step 608, the process 600 can move to step 608 wherein the snippet is stored in a memory. In this way, the snippet generated from the E2E can represent a separate model from the E2E model that includes a portion of the E2E model pertinent to the user's desired analysis. As will be explained below, the generated snippet can be used to as a frame, to upload more detailed data/information that can be used to create a full digital model of a snippet that can be used by one or more analysis tools to perform digital system engineering analysis on an SoS.

In one or more examples, while a snippet can include the constituent systems, subsystems, mission metrics, and mission threads that could be required for a particular analysis, it may not contain all of the data necessary to run a particular analysis. As discussed above, the E2E model from which a snippet can be generated, may purposefully exclude information about the system that may be required for a particular analysis, and thus may represent an incomplete digital model of an SoS. However, as explained above, excluding certain information from the E2E model minimizes the complexity of the model, and thus allows for the E2E model to represent an entire SoS. However, the E2E model itself may not include the necessary information that a full digital model could provide to perform a particular analysis. In one or more examples, once a snippet is created (i.e., a subset of the E2E model), the data withheld from the E2E model can be added back as needed to further populate the enhanced analysis model, which can represent a full digital model of the portion of the SoS, represented in a snippet. This enhanced model can then be used by an analysis tool to perform a detailed analysis regarding an SoS. In most cases, the data in the top-level model will not be sufficient to address the issue, but it provides the frame to add additional data or to enhance the current representations based on available detailed models. Starting with the ‘snippet’, the models are enhanced and expanded to include added attributes and behaviors needed to address the specific issues, using other data and more detailed models acquired for the analysis.

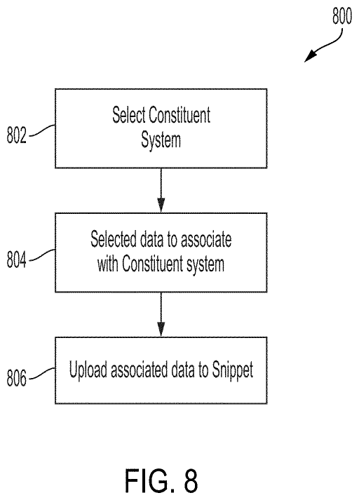

FIG. 8 illustrates an exemplary process for generating an enhanced analysis model based on a generated snippet according to examples of the disclosure. In one or more examples, the process 800 of FIG. 8 can be performed on a snippet created using the process outlined above with respect to FIG. 6. Using the snippet as a starting point, the process 800 of FIG. 8 can begin at step 802, wherein one or more constituent systems are selected by a user to be enhanced. In one or more examples, and additionally or alternatively to the examples above, a user can select subsystems of a constituent systems, connections between systems, mission threads, and/or mission metrics to also add additional data for an enhancement model. In one or more examples, the components can be selected using an architectural modeling language such as SysML. In one or more examples, selection of a constituent system can also cause selection of any subsystems, mission threads, and/or metrics associated with a selected system.

In one or more examples, once a component of the snippet has been selected by a user at step 802, the process 800 can move to step 804 wherein a user can select (via a graphical user interface or other methods for transmitting user intent to a computing device) one or more data sources to associate with the selected constituent system (or other component of the snippet). In one or more examples, the user can select the data at step 804 based on the component of the snippet that was selected at step 802. In one or more examples, the data selected at step 804 can include data regarding the selected component, more detailed models related to the selected component, other attributes of the selected component that were not part of the E2E model/snippet, and other behaviors that may be needed to address specific analysis needs of the user and the SoS. In one or more examples, selecting the component at step 802 and identifying data associated with the component can ensure that any data analysis tool is able to interpret the data selected at step 804 as belonging or being related to a particular component of the snippet.

In one or more examples, once the data has been selected at step 804, the process 800 can move to step 804 wherein the associated data is uploaded to the snippet model for inclusion as part of the model to form the enhanced model. In one or more examples, the process 800 described above can repeated for as many of the constituent systems, subsystems, connections, metrics, and/or mission threads as desired by the user and as needed for the user to conduct a particular analysis. Once a user has completed adding data to the snippet to form an enhanced model, the resulting enhanced model can be used to perform the desired analysis. In one or more examples, the analysis can be conducted within the model-based system engineering environment, or in one or more examples, can be conducted in an external analysis environment that can ingest as input, the enhanced model generated using the process outlined above with respect to process 800 of FIG. 8.

As demonstrated above, generating a simplified E2E model of an SoS, and using the simplified model to create a snippet of interest which can then be used to create an enhanced and detailed model for analysis, can result in the a process in which a single unifying model of an SoS can be used to create multiple enhanced models for the detailed analysis associated with modern digital engineering analyses. The approach uses a top-level lightweight representation of the end-to-end SoS mission architecture by integrating systems and connectivity with mission threads and activities, as well as mission metrics, to frame the mission context. Using this E2E model as context, model ‘snippets’ are extracted and used as the base for enhanced analysis models to address and dive into specific issues with enhanced modeling as well as interfaces to analysis tools appropriate for the particular issue.

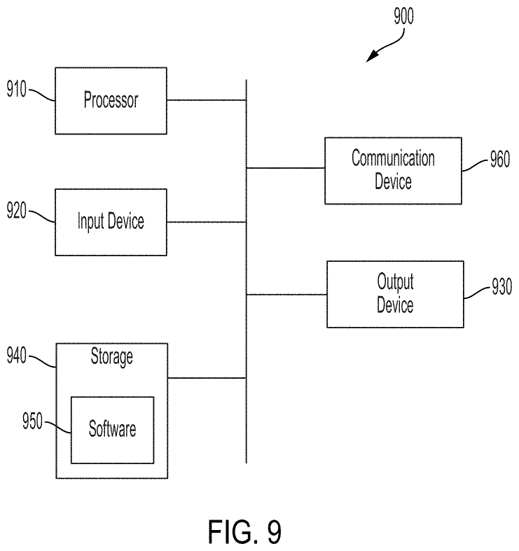

FIG. 9 illustrates an example of a computing system 900, in accordance with some examples of the disclosure. System 900 can be a client or a server. As shown in FIG. 9, system 900 can be any suitable type of processor-based system, such as a personal computer, workstation, server, handheld computing device (portable electronic device) such as a phone or tablet, or dedicated device. The system 900 can include, for example, one or more of input device 920, output device 930, one or more processors 910, storage 940, and communication device 960. Input device 920 and output device 930 can generally correspond to those described above and can either be connectable or integrated with the computer.

Input device 920 can be any suitable device that provides input, such as a touch screen, keyboard or keypad, mouse, gesture recognition component of a virtual/augmented reality system, or voice-recognition device. Output device 930 can be or include any suitable device that provides output, such as a display, touch screen, haptics device, virtual/augmented reality display, or speaker.

Storage 940 can be any suitable device that provides storage, such as an electrical, magnetic, or optical memory including a RAM, cache, hard drive, removable storage disk, or other non-transitory computer readable medium. Communication device 960 can include any suitable device capable of transmitting and receiving signals over a network, such as a network interface chip or device. The components of the computing system 900 can be connected in any suitable manner, such as via a physical bus or wirelessly.

Processor(s) 910 can be any suitable processor or combination of processors, including any of, or any combination of, a central processing unit (CPU), field programmable gate array (FPGA), and application-specific integrated circuit (ASIC). Software 950, which can be stored in storage 940 and executed by one or more processors 910, can include, for example, the programming that embodies the functionality or portions of the functionality of the present disclosure (e.g., as embodied in the devices as described above)

Software 950 can also be stored and/or transported within any non-transitory computer-readable storage medium for use by or in connection with an instruction execution system, apparatus, or device, such as those described above, that can fetch instructions associated with the software from the instruction execution system, apparatus, or device and execute the instructions. In the context of this disclosure, a computer-readable storage medium can be any medium, such as storage 940, that can contain or store programming for use by or in connection with an instruction execution system, apparatus, or device.

Software 950 can also be propagated within any transport medium for use by or in connection with an instruction execution system, apparatus, or device, such as those described above, that can fetch instructions associated with the software from the instruction execution system, apparatus, or device and execute the instructions. In the context of this disclosure, a transport medium can be any medium that can communicate, propagate or transport programming for use by or in connection with an instruction execution system, apparatus, or device. The transport computer readable medium can include, but is not limited to, an electronic, magnetic, optical, electromagnetic, or infrared wired or wireless propagation medium.

System 900 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

System 900 can implement any operating system suitable for operating on the network. Software 950 can be written in any suitable programming language, such as C, C++, Java, or Python. In various embodiments, application software embodying the functionality of the present disclosure can be deployed in different configurations, such as in a client/server arrangement or through a Web browser as a Web-based application or Web service, for example.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated. For the purpose of clarity and a concise description, features are described herein as part of the same or separate embodiments; however, it will be appreciated that the scope of the disclosure includes embodiments having combinations of all or some of the features described.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A method for generating an enhanced digital model for of a system of systems, the method comprising:
generating an end-to-end model of the system of systems, wherein the end-to-end model of the system of systems comprises a plurality of constituent systems of the systems of systems (SoS), and one or more connections between the plurality of constituent systems;
identifying one or more constituent systems of the SoS required to perform an analysis of the SoS;
generating a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS; and
associating data to the one or more constituent systems of the digital model; and
generating an enhanced analysis model based on the generated digital model and the data associated to the one or more constituent systems of the digital model.

2. The method of claim 1, wherein generating the end-to-end model comprises:
identifying the plurality constituent systems belonging to the SoS; and
identifying the one or more connections between the plurality of constituent systems;

3. The method of claim 2, wherein generating the end-to-end model comprises:
identifying one or more mission threads associated with the SoS; and
associating the one or more mission threads with plurality of constituent systems or the one or more connections between the plurality of constituent systems.

4. The method of claim 2, wherein generating the end-to-end model comprises:
identifying one or more mission metrics associated with the SoS; and
associating the one or more mission metrics with plurality of constituent systems or the one or more connections between the plurality of constituent systems.

5. The method of claim 1, wherein identifying one or more constituent systems of the SoS required to perform the analysis of the SoS comprises:
labelling each constituent system of the plurality of constituent systems with one or more stereotypes;
selecting a stereotype of the one or more stereotypes; and
identifying the one or more constituent systems of the SoS required to perform the analysis of the SoS based on the selected one or more stereotypes.

6. The method of claim 5, wherein identifying the one or more constituent systems of the SoS required to perform the analysis of the SoS comprises:
labelling one or more mission threads associated with the plurality of constituent systems with one or more stereotypes;
selecting a stereotype of the one or more stereotypes; and
identifying the one or more constituent systems of the SoS required to perform the analysis of the SoS based on the mission threads associated with the selected one or more stereotypes.

7. The method of claim 1, wherein generating the digital model comprises:
specifying one or more criteria associated with the digital model; and
selecting one or more constituent systems from the end-to-end model based on the identified one or more constituent systems of the SoS and the one or more criteria associated with the digital model.

8. The method of claim 7, wherein the one or more criteria associated with the digital model comprises a degree of connectivity between the identified constituent systems, and other constituent systems of the plurality of constituent systems of the end-to-end model.

9. The method of claim 1, wherein the data associated to the one or more constituent systems of the digital model includes information pertaining to the operation of the one or more constituent systems associated with the data.

10. The method of claim 1, wherein the end-to-end model, the digital model, and the enhanced analysis model are generated using SysML.

11. A system for generating an enhanced digital model for of a system of systems, the system comprising:
a memory;
one or more processors;
wherein the memory stores one or more programs that when executed by the one or more processors, cause the one or more processors to:
generate an end-to-end model of the system of systems, wherein the end-to-end model of the system of systems comprises a plurality of constituent systems of the systems of systems (SoS), and one or more connections between the plurality of constituent systems;
identify one or more constituent systems of the SoS required to perform an analysis of the SoS;
generate a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS; and
associate data to the one or more constituent systems of the digital model; and
generate an enhanced analysis model based on the generated digital model and the data associated to the one or more constituent systems of the digital model.

12. The system of claim 11, wherein generating the end-to-end model comprises:
identifying the plurality constituent systems belonging to the SoS; and
identifying the one or more connections between the plurality of constituent systems;

13. The system of claim 12, wherein generating the end-to-end model comprises:
identifying one or more mission threads associated with the SoS; and
associating the one or more mission threads with plurality of constituent systems or the one or more connections between the plurality of constituent systems.

14. The system of claim 12, wherein generating the end-to-end model comprises:
identifying one or more mission metrics associated with the SoS; and
associating the one or more mission metrics with plurality of constituent systems or the one or more connections between the plurality of constituent systems.

15. The system of claim 11, wherein identifying one or more constituent systems of the SoS required to perform the analysis of the SoS comprises:
labelling each constituent system of the plurality of constituent systems with one or more stereotypes;
selecting a stereotype of the one or more stereotypes; and
identifying the one or more constituent systems of the SoS required to perform the analysis of the SoS based on the selected one or more stereotypes.

16. The system of claim 15, wherein identifying the one or more constituent systems of the SoS required to perform the analysis of the SoS comprises:
labelling one or more mission threads associated with the plurality of constituent systems with one or more stereotypes;
selecting a stereotype of the one or more stereotypes; and
identifying the one or more constituent systems of the SoS required to perform the analysis of the SoS based on the mission threads associated with the selected one or more stereotypes.

17. The system of claim 11, wherein generating the digital model comprises:
specifying one or more criteria associated with the digital model; and
selecting one or more constituent systems from the end-to-end model based on the identified one or more constituent systems of the SoS and the one or more criteria associated with the digital model.

18. The system of claim 17, wherein the one or more criteria associated with the digital model comprises a degree of connectivity between the identified constituent systems, and other constituent systems of the plurality of constituent systems of the end-to-end model.

19. The system of claim 11, wherein the data associated to the one or more constituent systems of the digital model includes information pertaining to the operation of the one or more constituent systems associated with the data.

20. The system of claim 11, wherein the end-to-end model, the digital model, and the enhanced analysis model are generated using SysML.

21. A non-transitory computer readable storage medium storing one or more programs for generating an enhanced digital model for of a system of systems, the programs for execution by one or more processors of an electronic device that when executed by the device, cause the device to:
generate an end-to-end model of the system of systems, wherein the end-to-end model of the system of systems comprises a plurality of constituent systems of the systems of systems (SoS), and one or more connections between the plurality of constituent systems;
identify one or more constituent systems of the SoS required to perform an analysis of the SoS;
generate a digital model, wherein the digital model is based on the generated end-to-end model of the SoS and the identified one or more constituent systems, wherein the digital model includes one or more constituent system of the plurality of constituent systems of the SoS and one or more connections between the one or more constituent systems of the plurality of constituent systems of the SoS; and
associate data to the one or more constituent systems of the digital model; and
generate an enhanced analysis model based on the generated digital model and the data associated to the one or more constituent systems of the digital model.

22. The non-transitory computer readable storage medium of claim 21, wherein generating the end-to-end model comprises:
identifying the plurality constituent systems belonging to the SoS; and
identifying the one or more connections between the plurality of constituent systems;

23. The non-transitory computer readable storage medium of claim 22, wherein generating the end-to-end model comprises:
identifying one or more mission threads associated with the SoS; and
associating the one or more mission threads with plurality of constituent systems or the one or more connections between the plurality of constituent systems.

24. The non-transitory computer readable storage medium of claim 22, wherein generating the end-to-end model comprises:
identifying one or more mission metrics associated with the SoS; and
associating the one or more mission metrics with plurality of constituent systems or the one or more connections between the plurality of constituent systems.

25. The non-transitory computer readable storage medium of claim 21, wherein identifying one or more constituent systems of the SoS required to perform the analysis of the SoS comprises:
labelling each constituent system of the plurality of constituent systems with one or more stereotypes;
selecting a stereotype of the one or more stereotypes; and
identifying the one or more constituent systems of the SoS required to perform the analysis of the SoS based on the selected one or more stereotypes.

26. The non-transitory computer readable storage medium of claim 25, wherein identifying the one or more constituent systems of the SoS required to perform the analysis of the SoS comprises:
labelling one or more mission threads associated with the plurality of constituent systems with one or more stereotypes;
selecting a stereotype of the one or more stereotypes; and
identifying the one or more constituent systems of the SoS required to perform the analysis of the SoS based on the mission threads associated with the selected one or more stereotypes.

27. The non-transitory computer readable storage medium of claim 21, wherein generating the digital model comprises:
specifying one or more criteria associated with the digital model; and
selecting one or more constituent systems from the end-to-end model based on the identified one or more constituent systems of the SoS and the one or more criteria associated with the digital model.

28. The non-transitory computer readable storage medium of claim 27, wherein the one or more criteria associated with the digital model comprises a degree of connectivity between the identified constituent systems, and other constituent systems of the plurality of constituent systems of the end-to-end model.

29. The non-transitory computer readable storage medium of claim 21, wherein the data associated to the one or more constituent systems of the digital model includes information pertaining to the operation of the one or more constituent systems associated with the data.

30. The non-transitory computer readable storage medium of claim 21, wherein the end-to-end model, the digital model, and the enhanced analysis model are generated using SysML.
